(19) United States
(12) Patent Application Publication
(10) Pub. No.: US 2018/0270944 A1
(43) Pub. Date: Sep. 20, 2018

(54) POWER SUPPLY RELAY UNIT

(71) Applicant: FUJI ELECTRIC CO., LTD., Kawasaki-shi (JP)

(72) Inventor: Shinji HATAKENAKA, Suzuka-shi (JP)

(21) Appl. No.: 15/987,514

(22) Filed: May 23, 2018

Related U.S. Application Data
(63) Continuation of application No. PCT/JP2017/001263, filed on Jan. 16, 2017.

(30) Foreign Application Priority Data
Jun. 7, 2016 (JP) 2016-113261

(51) Int. Cl. H05K 1/02; G06F 1/18; G06F 1/20; H02J 7/02; H05K 1/18

(52) U.S. Cl. CPC H05K 1/0203; G06F 1/18; G06F 1/20; H05K 2201/10151; H05K 1/18; H05K 2201/10022; H05K 2201/10053; H02J 7/022

(57) ABSTRACT

In a power supply relay unit, in a plan view, a distance between a first switch disposed at a first end and a resistor disposed at a second end is equal to or larger than a width of at least one of the first switch and the resistor in a direction along which the first switch and the resistor are disposed.

### CROSS-REFERENCE TO RELATED APPLICATION

This application is a continuation of PCT application PCT/JP2017/001263, filed on Jan. 16, 2017, which is based upon and claims priority of Japanese patent application No. 2016-113261, filed on Jun. 7, 2016, the entire contents of which are incorporated herein by reference.

### BACKGROUND OF THE INVENTION

### Field of the Invention

The present invention relates to a power supply relay unit, and more particularly, it relates to a power supply relay unit provided between a power supply and a load.

### Description of the Background Art

In general, a power supply unit provided between a power supply and a load is known. Such a power supply unit is disclosed in International Publication No. WO2015/087437.

International Publication No. WO2015/087437 discloses a power converter provided between an AC power supply and an AC motor. This power converter includes a forward converter that converts AC power into DC power and a reverse converter that converts DC power into AC power having an arbitrary frequency. In the reverse converter, a switching device (semiconductor device) is provided. In this power converter, a shunt resistor configured to detect a current that flows through the switching device of the reverse converter is provided. In this power converter, a cooling fan configured to cool the forward converter and a power module (the switching device, for example) in the reverse converter is further provided.

However, in the conventional configuration in which the cooling fan cools the switching device or the like as in International Publication No. WO2015/087437, FIT (average failure rate per unit time) of the cooling fan is relatively large compared with those of the switching device and the resistor. That is, the cooling fan is relatively more likely to fail than the switching device and the resistor. Therefore, the lifetime of the apparatus including the cooling fan is disadvantageously shortened due to the failure of the cooling fan.

### SUMMARY OF THE INVENTION

The present invention has been proposed in order to solve the aforementioned problem, and one object of the present invention is to provide a power supply relay unit capable of suppressing lifetime shortening while performing sufficient cooling.

In order to attain the aforementioned object, a power supply relay unit according to an aspect of the present invention is provided between a DC power supply including a power supply unit that converts AC power into DC power and a battery unit that stores the DC power obtained by conversion by the power supply unit, and a load, and includes a first switch to which the DC power from the DC power supply is input, a resistor provided between the DC power supply and the first switch and configured to detect a current that flows from the DC power supply to the first switch, a first wiring pattern having a first end connected to the first switch and a second end connected to the resistor, and a second wiring pattern provided in a layer below a layer where the first wiring pattern is disposed, having an area larger than an area of the first wiring pattern, and having a potential different from a potential of the first wiring pattern. In a plan view, a distance between the first switch disposed at the first end and the resistor disposed at the second end is equal to or larger than a width of at least one of the first switch and the resistor in a direction along which the first switch and the resistor are disposed.

As hereinabove described, the power supply relay unit according to this aspect of the present invention includes the second wiring pattern provided in the layer below the layer where the first wiring pattern is disposed, having an area larger than the area of the first wiring pattern, and having a potential different from the potential of the first wiring pattern. Thus, the heat of the first wiring pattern, the temperature of which becomes relatively high due to heat generation from the first switch and the resistor, can be conducted to the second wiring pattern having an area larger than the area of the first wiring pattern, and hence the heat of the first wiring pattern can be dissipated and released into the second wiring pattern. Furthermore, in the plan view, the distance between the first switch disposed at the first end and the resistor disposed at the second end is equal to or larger than the width of at least one of the first switch and the resistor in the direction along which the first switch and the resistor are disposed. Thus, the distance between the first switch and the resistor becomes relatively large, and hence it is possible to suppress an increase in the temperature of the first wiring pattern due to thermal interference between the heat generated from the first switch and the heat generated from the resistor. Consequently, the temperatures of the first switch, the resistor, etc. provided in the power supply relay unit can be maintained at desired temperatures without providing a cooling fan in the power supply relay unit. That is, the temperatures can be maintained at desired temperatures without providing a cooling fan having a relatively short lifetime, and hence it is possible to suppress shortening of the lifetime of the power supply relay unit while sufficiently cooling the power supply relay unit.

In the aforementioned power supply relay unit according to this aspect, the second wiring pattern is preferably a signal ground wiring pattern through which a return current from the DC power supply flows. The power supply relay unit is configured to supply DC power from the DC power supply to the load, and hence a signal ground wiring pattern through which a return current from the DC power supply flows is provided in advance. Thus, the heat of the first wiring pattern can be dissipated and released into the signal ground wiring pattern without separately providing a wiring pattern for dissipating the heat of the first wiring pattern. Consequently, it is possible to sufficiently cool the power supply relay unit while suppressing complexity of the configuration.

The aforementioned power supply relay unit according to this aspect preferably further includes a substrate provided in a layer below a layer where the second wiring pattern is disposed, on which the first wiring pattern and the second wiring pattern are stacked, and an insulating layer provided between the first wiring pattern and the second wiring pattern and having a thickness smaller than a thickness of the substrate. According to this configuration, the heat of the first wiring pattern can be conducted to the second wiring pattern via the insulating layer having a relatively small thickness.

In this case, a thermal conductivity of the insulating layer is preferably larger than a thermal conductivity of the substrate. According to this configuration, the heat of the first wiring pattern can be efficiently conducted to the second wiring pattern via the insulating layer having a large thermal conductivity.

The aforementioned power supply relay unit according to this aspect preferably further includes a third wiring pattern provided in a layer below a layer where the second wiring pattern is disposed and having substantially a same potential as the first wiring pattern, and the first wiring pattern and the third wiring pattern are preferably connected to each other via a through-hole. According to this configuration, the heat of the first wiring pattern is also diffused into the third wiring pattern, and hence the power supply relay unit can be more sufficiently cooled.

The aforementioned power supply relay unit according to this aspect preferably further includes a third wiring pattern disposed in a same layer where the first wiring pattern is disposed and having an area larger than the area of the first wiring pattern, and the resistor is preferably connected so as to straddle the first wiring pattern and the third wiring pattern. According to this configuration, the heat of the resistor can be conducted to the third wiring pattern having an area larger than the area of the first wiring pattern and having a large heat releasing effect, and hence the power supply relay unit can be more sufficiently cooled.

The aforementioned power supply relay unit according to this aspect preferably further includes a second switch turned on to supply a first current to the load and activate a load-side controller of the load, and the first switch is preferably configured to, after the load-side controller of the load is activated, be turned on based on a request signal from the load-side controller of the load for requesting power supply to supply a second current larger than the first current to the load. The second current larger than the first current flows through the first switch, and hence the first switch generates a relatively large amount of heat. In this case, according to the present invention, the heat of the first wiring pattern, to which the first switch that generates a relatively large amount of heat is connected, can be diffused into the second wiring pattern, and the distance between the first switch and the resistor can be set to be relatively large. This is particularly useful for sufficiently cooling the power supply relay unit.

In the aforementioned power supply relay unit according to this aspect, the first switch and the resistor are preferably provided between the DC power supply and a server as the load. According to this configuration, shortening of the lifetime of the power supply relay unit is suppressed such that the number of times of maintenance of the server due to the lifetime of the power supply relay unit can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram of server systems (DC power supplies, power supply relay units, servers) according to an embodiment of the present invention;

FIG. 2 is a diagram showing a server system disposed in a server rack;

FIG. 3 is a block diagram of a power supply relay unit according to the embodiment of the present invention;

FIG. 4 is an exploded perspective view of the power supply relay unit according to the embodiment of the present invention;

FIG. 5 is a sectional view of a main substrate of the power supply relay unit according to the embodiment of the present invention;

FIG. 6 is a top view of the main substrate of the power supply relay unit according to the embodiment of the present invention;

FIG. 7 is a top view of a first layer of the main substrate of the power supply relay unit according to the embodiment of the present invention;

FIG. 8 is a top view of a second layer of the main substrate of the power supply relay unit according to the embodiment of the present invention;

FIG. 9 is a top view of a third layer of the main substrate of the power supply relay unit according to the embodiment of the present invention; and

FIG. 10 is a top view of a fourth layer of the main substrate of the power supply relay unit according to the embodiment of the present invention.

### DESCRIPTION OF THE PREFERRED EMBODIMENTS

Embodiments embodying the present invention are hereinafter described on the basis of the drawings.

### Present Embodiment

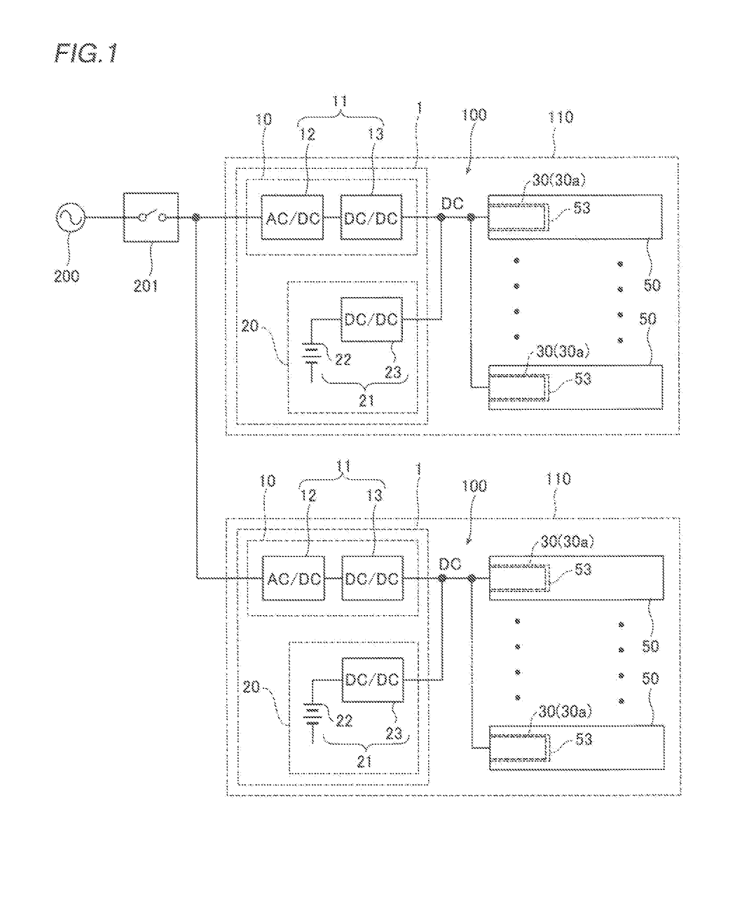

The configuration of a DC power supply system 100 (power supply relay units 30) according to the present embodiment is described with reference to FIGS. 1 to 10.

(Configuration of DC Power Supply System)

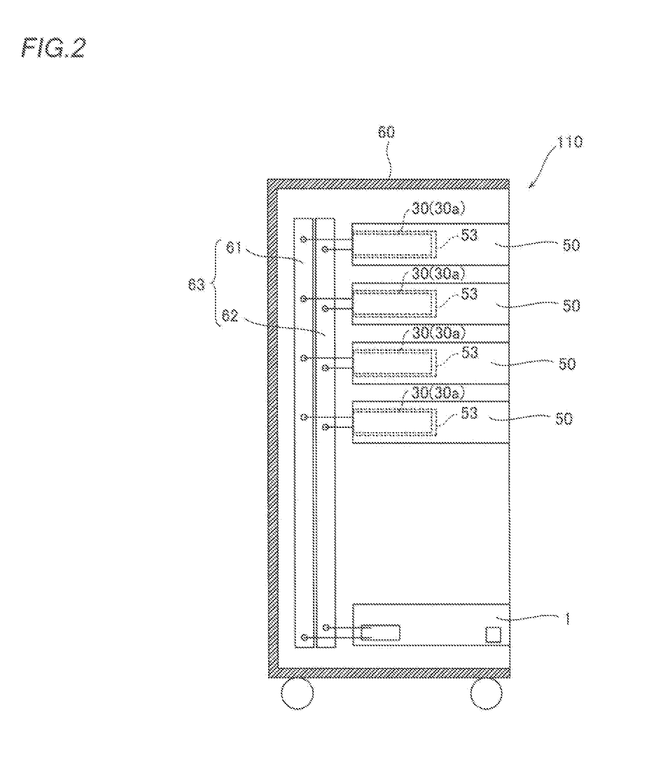

First, the schematic configuration of the DC power supply system 100 is described with reference to FIGS. 1 and 2. As shown in FIG. 1, the DC power supply system 100 includes a DC power supply 1 and the power supply relay units 30. The DC power supply system 100 is configured to convert AC power supplied from an AC power supply 200 into DC power and supply the DC power to a plurality of servers 50. The servers 50 are examples of a “load” in the claims.

The servers 50 each include a general AC server driven by converting input AC power into DC power. In a general AC server, a power supply unit (server-side power supply unit) (not shown) that converts AC power into DC power is provided. On the other hand, the servers 50 according to the present embodiment each include one obtained by removing the server-side power supply unit that converts AC power into DC power from the general existing AC server.

Furthermore, a DC power distribution device 201 is provided between the AC power supply 200 and the DC power supply system 100.

A plurality of sets (server systems 110) of the DC power supply 1, the power supply relay units 30, and the servers 50 are provided. The plurality of server systems 110 is connected in parallel to each other. That is, the DC power supply 1 is provided in each of the plurality of server systems 110. Thus, unlike the case where one DC power supply 1 is provided for the plurality of server systems 110, even if one of a plurality of DC power supplies 1 fails, it is possible to suppress stop of all the server systems 110.

(Configuration of DC Power Supply)

The DC power supply 1 includes a power supply unit 10 that converts AC power into DC power and a battery unit 20 that stores the DC power obtained by conversion by the power supply unit 10. The power supply unit 10 includes a power supply circuit 11. The power supply circuit 11 includes an AC-DC converter 12 and a DC-DC converter 13. The AC power supplied from the AC power supply 200 is converted into DC power by the AC-DC converter 12. The DC power obtained by conversion by the AC-DC converter 12 is converted into DC power having a predetermined voltage by the DC-DC converter 13. The DC power, the voltage of which has been converted into the predetermined voltage by the DC-DC converter 13, is supplied to the servers 50.

The battery unit 20 includes a battery circuit 21. The battery circuit 21 includes a battery 22 charged with DC power and a DC-DC converter 23 that bi-directionally conducts DC power. The battery 22 is connected in parallel to the power supply circuit 11 via the DC-DC converter 23 capable of bi-directionally conducting DC power. Furthermore, the battery 22 is charged with DC power by the power supply circuit 11 via the DC-DC converter 23, and supplies the charged DC power to the servers 50 via the DC-DC converter 23. That is, the DC power supply 1 normally supplies DC power from the power supply circuit 11 to the servers 50, and supplies DC power from the battery circuit 21 to the servers 50 when DC power is not supplied from the power supply circuit 11, such as in the event of a power failure.

As shown in FIG. 2, the DC power supply 1 and the plurality of servers 50 are disposed in a server rack 60. The DC power supply 1 is disposed in a lower portion of the server rack 60. The plurality of servers 50 is disposed above the DC power supply 1. In the server rack 60, a conductor 63 including a positive electrode conductor 61 and a negative electrode conductor 62 is provided. The power supply relay units 30 are electrically connected to the conductor 63. In addition, the plurality of servers 50 is connected in parallel to the conductor 63. The DC power output from the DC power supply 1 is supplied to the plurality of servers 50 via the conductor 63 and the power supply relay units 30.

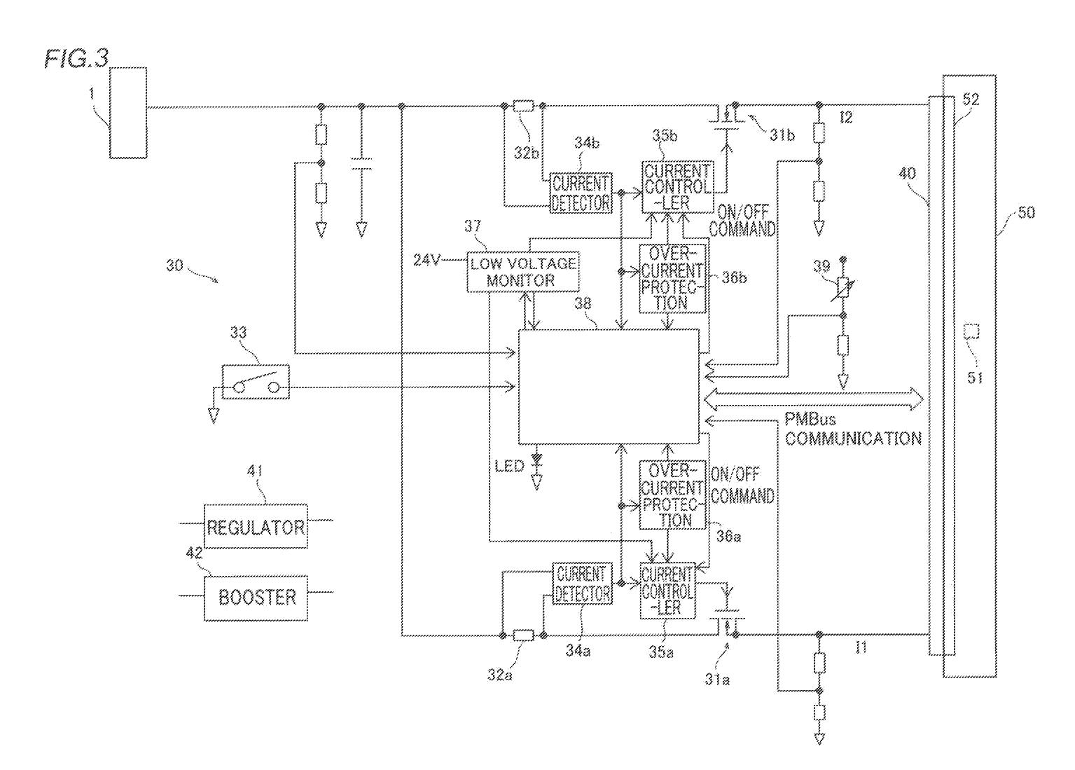

As shown in FIG. 2, the servers 50 each include an enclosure 53 capable of housing a server-side power supply unit that converts AC power into DC power. The power supply relay units 30 (power supply relay unit main bodies 30a) are disposed in the enclosures 53 of the servers 50, each of which is capable of housing a server-side power supply unit, in a state where a connection 40 is directly connected to a server-side connection 52 (see FIG. 3).

As shown in FIG. 2, a plurality of power supply relay units 30 is provided so as to correspond to the plurality of servers 50. Specifically, in one server system 110, one DC power supply 1 and the plurality of servers 50 are provided. One (or more) power supply relay unit 30 is provided in each of the plurality of servers 50.

(Circuit Configuration of Power Supply Relay Unit)

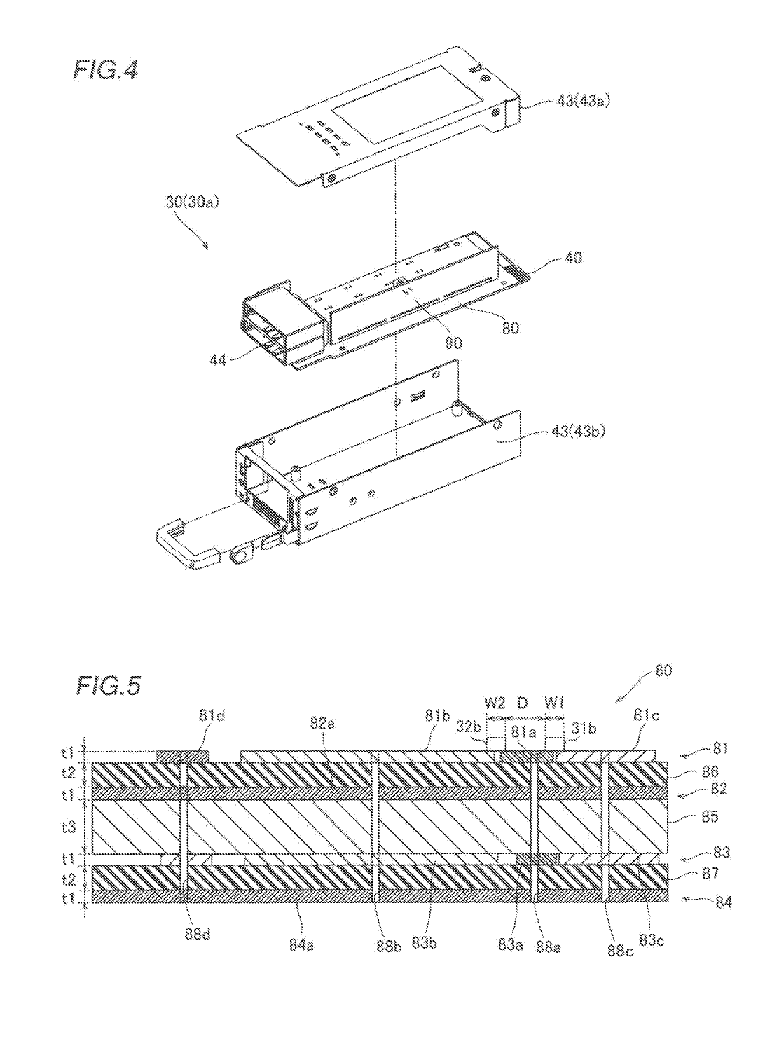

Next, the circuit configuration of one of the power supply relay units 30 according to the present embodiment is described with reference to FIGS. 3 and 4.

As shown in FIG. 3, the power supply relay unit 30 includes a switch 31a. The switch 31a is configured to receive the DC power from the DC power supply 1 via a shunt resistor 32a. The switch 31a is configured to be turned on to supply a current I1 of 12 V and 2 A, for example, to one of the servers 50 and activate a server-side controller 51 of the server 50. The switch 31a is an example of a “second switch” in the claims. The current I1 is an example of a “first current” in the claims. The server-side controller 51 is an example of a “load-side controller” in the claims.

The switch 31a includes an FET (Field Effect Transistor), for example. The shunt resistor 32a is connected to a drain of the switch 31a, and the connection 40 described later is connected to a source thereof. A current controller 35a described later is connected to a gate of the switch 31a.

The power supply relay unit 30 further includes a switch 33. The switch 33 includes a mechanical switch, for example. The switch 33 is configured to be turned on to turn on the switch 31a. Specifically, after a signal indicating that the switch 33 has been turned on is input to a controller 38, a signal for turning on the switch 31a is output from the controller 38.

The power supply relay unit 30 further includes a switch 31b. The switch 31b is configured to receive the DC power from the DC power supply 1 via a shunt resistor 32b. According to the present embodiment, the switch 31b is configured to, after the server-side controller 51 of the server 50 is activated, be turned on based on a request signal from the server-side controller 51 of the server 50 for requesting power supply to supply a current I2 of 12 V and 100 A, for example, larger than the current I1 to the server 50. Specifically, after the request signal from the server-side controller 51 of the server 50 for requesting power supply, including a command based on the PMBus (registered trademark) standard is input to the controller 38, a signal for turning on the switch 31b is output from the controller 38. The switch 31b is an example of a “first switch” in the claims. The current I2 is an example of a “second current” in the claims. The shunt resistor 32b is an example of a “resistor” in the claims.

The switch 31b includes an FET (Field Effect Transistor), for example. The connection 40 described later is connected to a source of the switch 31b, and the shunt resistor 32b is connected to a drain thereof. That is, according to the present embodiment, the switch 31b and the shunt resistor 32b are provided between the DC power supply 1 and the server 50. A current controller 35b described later is connected to a gate of the switch 31b. The switch 31a and the switch 31b are connected in parallel to each other.

In addition, a current detector 34a is provided at both ends of the shunt resistor 32a. A current detector 34b is also provided at both ends of the shunt resistor 32b. The shunt resistors 32a and 32b (current detectors 34a and 34b) are configured to detect a current value of a current that flows through the server 50. A signal from the current detector 34a is output to the current controller 35a, an overcurrent protection 36a, and the controller 38. A signal from the current detector 34b is output to the current controller 35b, an overcurrent protection 36b, and the controller 38.

On the output side of the current detector 34a, the current controller 35a is provided. The current controller 35a is configured to output a signal to the gate of the switch 31a. On the output side of the current detector 34b, the current controller 35b is provided. The current controller 35b is configured to output a signal to the gate of the switch 31b. The current controller 35a is configured to gently turn on the switch 31a. The current controller 35b is configured to gently turn on the switch 31b. When the switches 31a and 31b are abruptly turned on, the switches 31a and 31b may be damaged due to a large inrush current for charging a load capacitor (not shown) on the server 50 side. Therefore, the switches 31a and 31b are gently turned on.

Signals from the current detector 34a, the overcurrent protection 36a, the controller 38, and a low voltage monitor 37 are input to the current controller 35a. Signals from the current detector 34b, the overcurrent protection 36b, the controller 38, and the low voltage monitor 37 are input to the current controller 35b.

On the output side of the current detector 34a, the overcurrent protection 36a is provided. The signal from the overcurrent protection 36a is output to the current controller 35a and the controller 38. On the output side of the current detector 34b, the overcurrent protection 36b is provided. The signal from the overcurrent protection 36b is output to the current controller 35b and the controller 38. The overcurrent protections 36a and 36b are configured to suppress damages of the switches 31a and 31b due to short-circuit currents when the output of the switch 31a, which is a sub output, and the output of the switch 31b, which is a main output, are short-circuited. When the overcurrent protections 36a and 36b are configured by software, there are cases where it is not possible to suppress damages of the switches 31a and 31b, and hence the overcurrent protections 36a and 36b are configured by hardware.

The power supply relay unit 30 further includes the low voltage monitor 37. The signal from the controller 38 is input to the low voltage monitor 37. The signal from the low voltage monitor 37 is output to the current controller 35a, the current controller 35b, and the controller 38. The low voltage monitor 37 is configured to suppress damages of the switches 31a and 31b when a low voltage (24 V, for example) drops due to, for example, a failure of a booster 42 described later during operation of the power supply relay unit 30 (server 50).

The power supply relay unit 30 further includes the controller 38. The controller 38 is configured to control whether the switches 31a and 31b are on or off so as to supply the DC power from the DC power supply 1 to the server 50. Specifically, the controller 38 transmits a signal to the current controller 35a, and controls whether the switch 31a is on or off via the current controller 35a. In addition, the controller 38 transmits a signal to the current controller 35b, and controls whether the switch 31b is on or off via the current controller 35b. The controller 38 includes a microcomputer, for example.

Signals from the current detectors 34a and 34b, the overcurrent protections 36a and 36b, the low voltage monitor 37, and the switch 33 are input to the controller 38. Information on the power of the shunt resistors 32a and 32b on the input side, information on the power of the switches 31a and 31b on the server 50 side, and an output from a thermistor 39 are input to the controller 38. In addition, a signal is output from the controller 38 to a light source such as an LED.

The controller 38 is configured to be capable of communicating with the server 50 based on the PMBus (registered trademark) standard. The PMBus is a standard for managing a power supply, and communication between devices is performed by exchanging commands. Furthermore, the controller 38 is configured to return preset dummy information on AC input power to the server 50 in response to a request signal from the server 50 for requesting information on the AC input power. Thus, the preset dummy information on the AC input power is returned from the power supply relay unit 30, and hence it is possible to suppress stop of the server 50 due to failure to obtain appropriate information on the AC input power.

The power supply relay unit 30 further includes a regulator 41. The regulator 41 is configured to step down (3.3 V, for example) an input voltage (12 V, for example). The power supply relay unit 30 further includes the booster 42. The booster 42 is configured to boost (24 V, for example) the input voltage (12 V, for example).

(Specific Structure of Power Supply Relay Unit)

Next, the specific structure of the power supply relay unit 30 according to the present embodiment is described with reference to FIGS. 4 to 10.

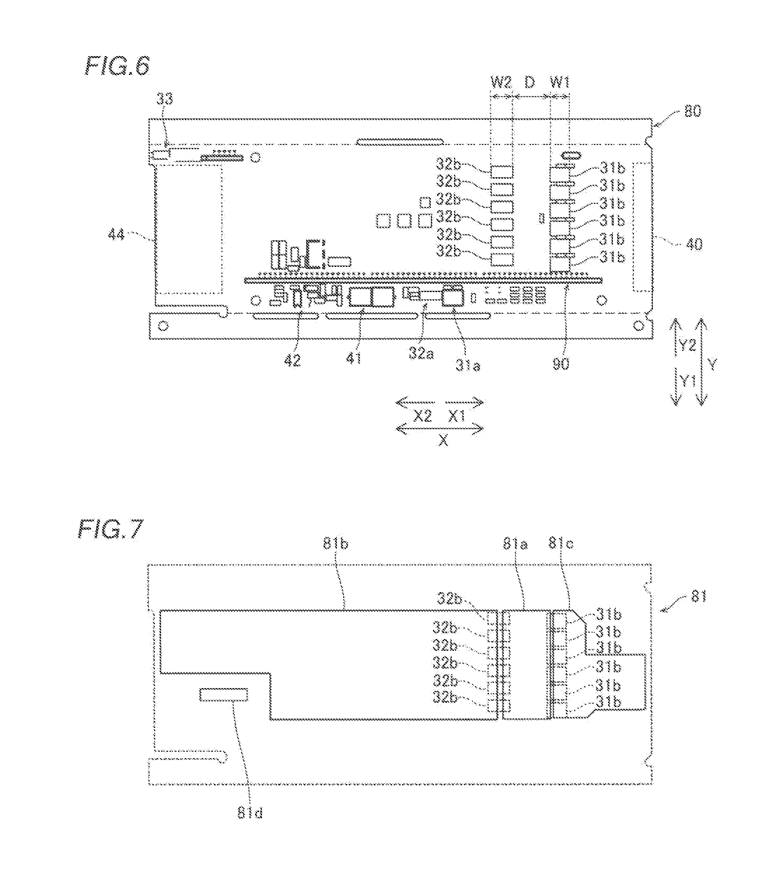

As shown in FIG. 4, the power supply relay unit 30 includes a housing 43 including an upper housing 43a and a lower housing 43b. The power supply relay unit 30 further includes a main substrate 80 on which the switches 31a and 31b, the shunt resistors 32a and 32b, etc. are disposed and an auxiliary substrate 90 on which the controller 38 etc. are disposed. As shown in FIG. 6, the connection 40 is provided at an end of the substrate 80 on an X1 direction side. The switch 31a and the shunt resistor 32a are disposed on the Y1 direction side of the main substrate 80. In addition, a plurality of switches 31b and a plurality of shunt resistors 32b are disposed along a Y direction on the X1 direction side of the main substrate 80.

<Structure of Main Substrate>

As shown in FIG. 5, the main substrate 80 includes a plurality of layers (a first layer 81 to a fourth layer 84). Specifically, in the main substrate 80, a second layer 82, an insulating layer 86, and the first layer 81 are stacked in this order above a substrate 85 made of glass epoxy. Furthermore, a third layer 83, an insulating layer 87, and the fourth layer 84 are stacked in this order below the substrate 85. A description is made below in order from the first layer 81.

As shown in FIG. 7, the first layer 81 of the main substrate 80 includes a wiring pattern 81a having a first end (X1 direction side) connected to the switch 31b and a second end (X2 direction side) connected to the shunt resistor 32b. The wiring pattern 81a is made of copper foil, for example, and has a thickness t1 (see FIG. 5). The wiring pattern 81a is an example of a “first wiring pattern” in the claims.

According to the present embodiment, in a planar view, a distance D between the switch 31b disposed at the first end and the shunt resistor 32b disposed at the second end is equal to or larger than the width of at least one of the switch 31b (width W1) and the shunt resistor 32b (width W2) in a direction (X direction) along a direction in which the switch 31b and the shunt resistor 32b are disposed, as shown in FIG. 6. Specifically, the distance D is larger than both the width W1 of the switch 31b and the width W2 of the shunt resistor 32b. The distance D is a distance between an end of the shunt resistor 32b on the X1 direction side and an end of the switch 31b on the X2 direction side.

According to the present embodiment, a wiring pattern 81b having an area larger than the area of the wiring pattern 81a is disposed in the same layer (first layer 81) where the wiring pattern 81a is disposed. The wiring pattern 81b is made of copper foil, for example, and has a thickness t1 (see FIG. 5) substantially the same as that of the wiring pattern 81a. The shunt resistor 32b is connected so as to straddle the wiring pattern 81a and the wiring pattern 81b. DC power (12 V, 100 A, for example) is input to the wiring pattern 81b via an input connector 44. The wiring pattern 81b is an example of a “third wiring pattern” in the claims.

In the same layer (first layer 81) where the wiring pattern 81a is disposed, a wiring pattern 81c is disposed. The wiring pattern 81c is made of copper foil, for example, and has a thickness t1 (see FIG. 5) substantially the same as that of the wiring pattern 81a. The switch 31b is connected so as to straddle the wiring pattern 81a and the wiring pattern 81c. DC power is output from the wiring pattern 81c.

In the first layer 81, a wiring pattern 81d having the same potential as the wiring pattern 82a, which is a signal ground wiring pattern described later, is disposed.

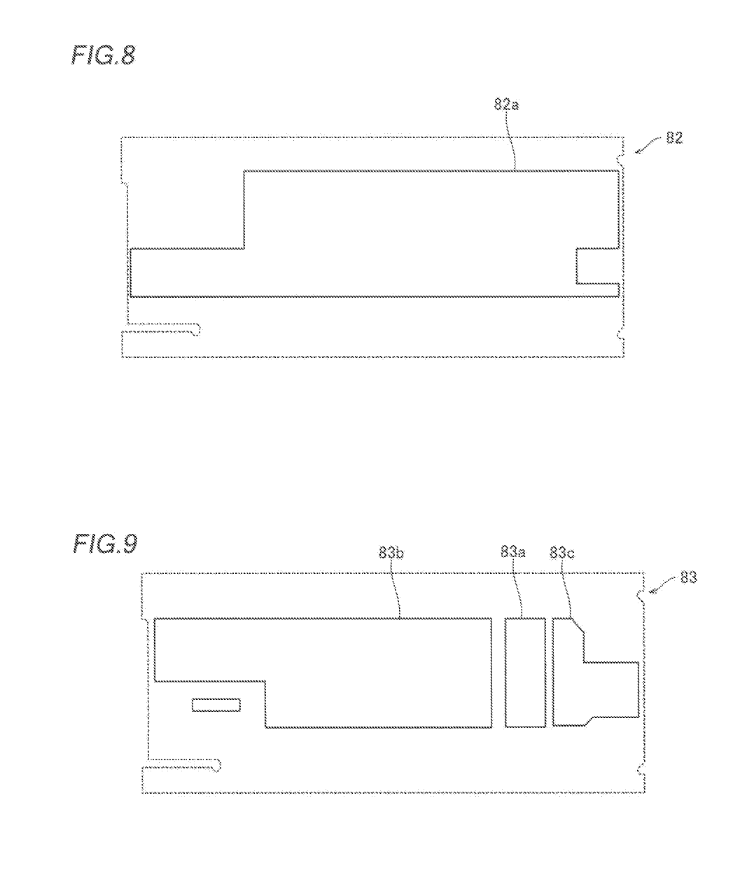

According to the present embodiment, in a layer (second layer 82) below the layer where the wiring pattern 81a is disposed, a wiring pattern 82a having an area larger than the area of the wiring pattern 81a (and the wiring pattern 81b and the wiring pattern 81c) and having a potential different from the potential of the wiring pattern 81a is provided, as shown in FIG. 8. Specifically, the wiring pattern 82a is a signal ground wiring pattern through which a return current from the DC power supply 1 flows. The wiring pattern 82a is made of copper foil, for example, and has a thickness t1 (see FIG. 5) substantially the same as that of the wiring pattern 81a. The wiring pattern 82a is an example of a “second wiring pattern” in the claims.

In the plan view, the wiring pattern 82a overlaps the wiring pattern 81a, the wiring pattern 81b, and the wiring pattern 81c of the first layer 81.

As shown in FIG. 5, the insulating layer 86 is provided between the wiring pattern 81a (first layer 81) and the wiring pattern 82a (second layer 82). The insulating layer 86 is made of prepreg (registered trademark), for example. The prepreg is a sheet-like material in which a resin is impregnated into carbon fibers. According to the present embodiment, the insulating layer 86 has a thickness t2 smaller than the thickness t3 of the substrate 85 described later. For example, the thickness t2 of the insulating layer 86 is approximately ½ of the thickness t3 of the substrate 85. The thickness t2 of the insulating layer 86 is larger than the thickness t1 of the wiring pattern 81a and the like. For example, the thickness t2 of the insulating layer 86 is about three times the thickness t1 of the wiring pattern 81a and the like. In addition, the insulating layer 86 is disposed in a region corresponding to substantially the entire upper surface of the substrate 85 described later.

The substrate 85 on which the wiring pattern 81a, the wiring pattern 82a, etc. are stacked is provided in a layer below a layer where the wiring pattern 82a is disposed. The substrate 85 is made of glass epoxy, for example. The substrate 85 has a thickness t3.

According to the present embodiment, the thermal conductivity of the insulating layer 86 (and the insulating layer 87 described later) is larger than the thermal conductivity of the substrate 85. Specifically, the thermal conductivity of the insulating layer 86 (insulating layer 87) made of prepreg is larger than the thermal conductivity of the substrate 85 made of glass epoxy.

According to the present embodiment, as shown in FIGS. 5 and 9, a wiring pattern 83a having substantially the same potential as the wiring pattern 81a is provided in a layer (third layer 83) below the layer (second layer 82) where the wiring pattern 82a is disposed. The wiring pattern 81a and the wiring pattern 83a are connected to each other via a through-hole 88a. The wiring pattern 83a is made of copper foil, for example, and has a thickness t1 (see FIG. 5) substantially the same as that of the wiring pattern 81a. The wiring pattern 83a is an example of a “third wiring pattern” in the claims.

In FIG. 5, wiring patterns connected to each other via a through-hole 88a, 88b, 88c, or 88d are shown by dotted lines in the corresponding through-hole 88a, 88b, 88c, or 88d.

As shown in FIGS. 5 and 9, the third layer 83 includes a wiring pattern 83b having a potential (12 V) substantially the same as the potential of the wiring pattern 81b. The wiring pattern 83b functions as a wiring pattern on the input side. As shown in FIG. 5, the wiring pattern 81b and the wiring pattern 83b are connected to each other via the through-hole 88b. The wiring pattern 83b is made of copper foil, for example, and has a thickness t1 substantially the same as that of the wiring pattern 81a.

As shown in FIGS. 5 and 9, the third layer 83 includes a wiring pattern 83c having a potential (12 V) substantially the same as the potential of the wiring pattern 81c. The wiring pattern 81c functions as a wiring pattern on the output side. The wiring pattern 81c and the wiring pattern 83c are connected to each other via the through-hole 88c. The wiring pattern 83c is made of copper foil, for example, and has a thickness t1 substantially the same as that of the wiring pattern 81a.

As shown in FIG. 5, the insulating layer 87 made of prepreg, for example, is disposed in a layer below a layer where the wiring pattern 83b and the wiring pattern 83c are disposed. The insulating layer 87 is disposed in a region corresponding to substantially the entire lower surface of the substrate 85.

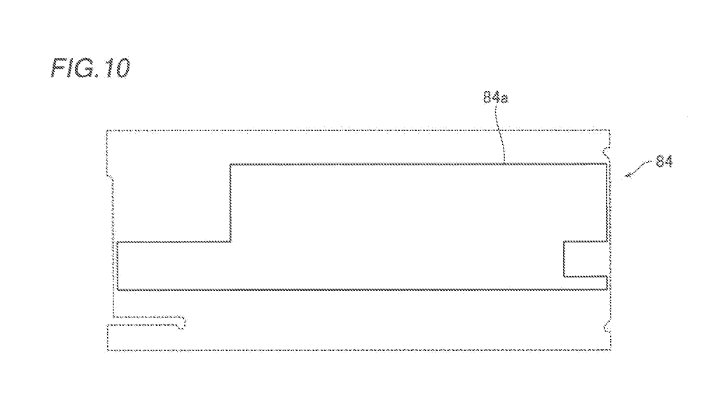

As shown in FIGS. 5 and 10, a layer (fourth layer 84) below the insulating layer 87 includes a wiring pattern 84a having an area larger than the area of each of the wiring pattern 83a, the wiring pattern 83b, and the wiring pattern 83c and having a potential different from the potential of the wiring pattern 83a. Specifically, the wiring pattern 84a is a signal ground wiring pattern through which a return current from the DC power supply 1 flows. The wiring pattern 84a is made of copper foil, for example, and has a thickness t1 substantially the same as that of the wiring pattern 81a.

In the plan view, the wiring pattern 84a overlaps the wiring pattern 83a, the wiring pattern 83b, and the wiring pattern 83c of the third layer 83 (the wiring pattern 81a, the wiring pattern 81b, and the wiring pattern 81c of the first layer 81).

The wiring pattern 84a is connected to the wiring pattern 81d and the wiring pattern 82a via the through-hole 88d.

<Current Flow>

As shown in FIG. 5, a current (current I2) from the DC power supply 1 flows into the wiring pattern 81b and the wiring pattern 81c via the input connector 44. The current that has flowed into the wiring pattern 81c flows into the wiring pattern 81b via the through-hole 88b. Then, the current that has flowed into the wiring pattern 81b flows out of the wiring pattern 81c and the wiring pattern 83c to the server 50 via the shunt resistor 32b, the wiring pattern 81a, and the switch 31b.

<Heat Diffusion>

As shown in FIG. 5, a current (current I2) from the DC power supply 1 flows through the shunt resistor 32b, the wiring pattern 81a, and the switch 31b such that relatively high-temperature heat generated from the shunt resistor 32b and the switch 31b is conducted to the wiring pattern 81a. The heat conducted to the wiring pattern 81a is diffused into the wiring pattern 82a via the insulating layer 86. The area of the wiring pattern 82a is larger than that of the wiring pattern 81a, and hence the heat from the wiring pattern 81a is efficiently conducted to the wiring pattern 82a.

The heat conducted to the wiring pattern 81a is also diffused into the wiring pattern 83a via the through-hole 88a.

The heat generated from the shunt resistor 32b is diffused into the wiring pattern 81b, and is diffused into the wiring pattern 83b via the through-hole 88b. The heat generated from the switch 31b is diffused into the wiring pattern 81c, and is diffused into the wiring pattern 83c via the through-hole 88c.

Thus, the heat from the shunt resistor 32b, the wiring pattern 81a, and the switch 31b is diffused such that the temperatures of the switch 31b, the shunt resistor 32b, etc. can be maintained at desired temperatures without providing a cooling fan.

(Effects of Present Embodiment)

According to the present embodiment, the following effects can be obtained.

According to the present embodiment, as hereinabove described, the power supply relay unit 30 includes the wiring pattern 82a provided in the layer below the layer where the wiring pattern 81a is disposed, having an area larger than the area of the wiring pattern 81a, and having a potential different from the potential of the wiring pattern 81a. Thus, the heat of the wiring pattern 81a, the temperature of which becomes relatively high due to heat generation from the switch 31b and the shunt resistor 32b, can be conducted to the wiring pattern 82a having an area larger than the area of the wiring pattern 81a, and hence the heat of the wiring pattern 81a can be dissipated and released into the wiring pattern 82a. Furthermore, in the plan view, the distance D between the switch 31b disposed at the first end and the shunt resistor 32b disposed at the second end is equal to or larger than the width of at least one of the switch 31b and the shunt resistor 32b in the direction along the direction in which the switch 31b and the shunt resistor 32b are disposed. Thus, the distance D between the switch 31b and the shunt resistor 32b becomes relatively large, and hence it is possible to suppress an increase in the temperature of the wiring pattern 81a due to thermal interference between the heat generated from the switch 31b and the heat generated from the shunt resistor 32b. Consequently, the temperatures of the switch 31b, the shunt resistor 32b, etc. provided in the power supply relay unit 30 can be maintained at desired temperatures without providing a cooling fan in the power supply relay unit 30. That is, the temperatures can be maintained at desired temperatures without providing a cooling fan having a relatively short lifetime, and hence it is possible to suppress shortening of the lifetime of the power supply relay unit 30 while sufficiently cooling the power supply relay unit 30.

According to the present embodiment, as hereinabove described, the wiring pattern 82a is a signal ground wiring pattern through which a return current from the DC power supply 1 flows. The power supply relay unit 30 is configured to supply DC power from the DC power supply 1 to the server 50, and hence a signal ground wiring pattern through which a return current from the DC power supply 1 flows is provided in advance. Thus, the heat of the wiring pattern 81a can be dissipated and released into the signal ground wiring pattern without separately providing a wiring pattern for dissipating the heat of the wiring pattern 81a. Consequently, it is possible to sufficiently cool the power supply relay unit 30 while suppressing complexity of the configuration.

According to the present embodiment, as hereinabove described, the power supply relay unit 30 includes the substrate 85 provided in the layer below the layer where the wiring pattern 82a is disposed, on which the wiring pattern 81a and the wiring pattern 82a are stacked, and the insulating layer 86 provided between the wiring pattern 81a and the wiring pattern 82a and having a thickness t2 smaller than the thickness t3 of the substrate 85. Thus, the heat of the wiring pattern 81a can be conducted to the wiring pattern 82a via the insulating layer 86 having a relatively small thickness t2.

According to the present embodiment, as hereinabove described, the thermal conductivity of the insulating layer 86 is larger than the thermal conductivity of the substrate 85. Thus, the heat of the wiring pattern 81a can be efficiently conducted to the wiring pattern 82a via the insulating layer 86 having a large thermal conductivity.

According to the present embodiment, as hereinabove described, the wiring pattern 83a having substantially the same potential as the wiring pattern 81a is provided in the layer below the layer where the wiring pattern 82a is disposed, and the wiring pattern 81a and the wiring pattern 83a are connected to each other via the through-hole 88a. Thus, the heat of the wiring pattern 81a is also diffused into the wiring pattern 83a, and hence the power supply relay unit 30 can be more sufficiently cooled.

According to the present embodiment, as hereinabove described, the wiring pattern 81b having an area larger than the area of the wiring pattern 81a is provided in the same layer where the wiring pattern 81a is disposed. Furthermore, the shunt resistor 32b is connected so as to straddle the wiring pattern 81a and the wiring pattern 81b. Thus, the heat of the shunt resistor 32b can be conducted to the wiring pattern 81b having an area larger than the area of the wiring pattern 81a and having a large heat releasing effect, and hence the power supply relay unit 30 can be more sufficiently cooled.

According to the present embodiment, as hereinabove described, the power supply relay unit 30 includes the switch 31a turned on to supply the current I1 to the server 50 and activate the server-side controller 51 of the server 50. Furthermore, the switch 31b is configured to, after the server-side controller 51 of the server 50 is activated, be turned on based on the request signal from the server-side controller 51 of the server 50 for requesting power supply to supply the current I2 larger than the current I1 to the server 50. The current I2 larger than the current I1 flows through the switch 31b, and hence the switch 31b generates a relatively large amount of heat. In this case, according to the present embodiment, the heat of the wiring pattern 81a, to which the switch 31b that generates a relatively large amount of heat is connected, can be diffused into the wiring pattern 82a, and the distance D between the switch 31b and the shunt resistor 32b can be set to be relatively large. This is particularly useful for sufficiently cooling the power supply relay unit 30.

According to the present embodiment, as hereinabove described, the switch 31b and the shunt resistor 32b are provided between the DC power supply 1 and the server 50. Thus, shortening of the lifetime of the power supply relay unit 30 is suppressed such that the number of times of maintenance of the server 50 due to the lifetime of the power supply relay unit 30 can be reduced.

[Modifications]

The embodiment disclosed this time must be considered as illustrative in all points and not restrictive. The range of the present invention is not shown by the above description of the embodiment but by the scope of claims for patent, and all modifications within the meaning and range equivalent to the scope of claims for patent are further included.

For example, while the example in which in the plan view, the distance between the switch and the shunt resistor is equal to or larger than the width of the switch and the width of the shunt resistor has been shown in the aforementioned embodiment, the present invention is not restricted to this. For example, the distance between the switch and the shunt resistor may be equal to or larger than the width of one of the switch and the shunt resistor.

While the example in which the shunt resistor is used as the resistor according to the present invention has been shown in the aforementioned embodiment, the present invention is not restricted to this. For example, a resistor other than the shunt resistor may be used as the resistor according to the present invention.

While the example in which the heat of the wiring pattern 81a is diffused into the signal ground wiring pattern has been shown in the aforementioned embodiment, the present invention is not restricted to this. For example, the heat of the wiring pattern 81a may be diffused into a wiring pattern other than the signal ground wiring pattern.

While the example in which the insulating layer made of prepreg is used has been shown in the aforementioned embodiment, the present invention is not restricted to this. For example, an insulating layer made of a material other than the prepreg may be used.

While the example in which the plurality of switches and the plurality of shunt resistors are provided has been shown in the aforementioned embodiment, the present invention is not restricted to this. For example, one switch and one shunt resistor may be provided.

While the example in which the wiring patterns are made of copper foil has been shown in the aforementioned embodiment, the present invention is not restricted to this. For example, the wiring patterns may be made of a material other than the copper foil.

While the example in which the present invention is applied to the server as a load has been shown in the aforementioned embodiment, the present invention is not restricted to this. For example, the present invention may be applied to a load other than the server.

What is claimed is:

1. A power supply relay unit provided between a DC power supply including a power supply unit that converts AC power into DC power and a battery unit that stores the DC power obtained by conversion by the power supply unit, and a load, comprising:
a first switch to which the DC power from the DC power supply is adapted to be input;
a resistor adapted to be provided between the DC power supply and the first switch and configured to detect a current that flows from the DC power supply to the first switch;
a first wiring pattern having a first end connected to the first switch and a second end connected to the resistor; and
a second wiring pattern provided in a layer below a layer where the first wiring pattern is disposed, having an area larger than an area of the first wiring pattern, and having a potential different from a potential of the first wiring pattern,
wherein in a plan view, a distance between the first switch disposed at the first end and the resistor disposed at the second end is equal to or larger than a width of at least one of the first switch and the resistor in a direction along which the first switch and the resistor are disposed.

2. The power supply relay unit according to claim 1, wherein the second wiring pattern is a signal ground wiring pattern through which a return current from the DC power supply is adapted to flow.

3. The power supply relay unit according to claim 1, further comprising:
a substrate provided in a layer below a layer where the second wiring pattern is disposed, on which the first wiring pattern and the second wiring pattern are stacked; and
an insulating layer provided between the first wiring pattern and the second wiring pattern and having a thickness smaller than a thickness of the substrate.

4. The power supply relay unit according to claim 3, wherein the insulating layer has a thermal conductivity larger than a thermal conductivity of the substrate.

5. The power supply relay unit according to claim 1, further comprising a third wiring pattern provided in a layer below a layer where the second wiring pattern is disposed, and having a potential substantially same as that of the first wiring pattern,
wherein the first wiring pattern and the third wiring pattern are connected to each other via a through-hole.

6. The power supply relay unit according to claim 1, further comprising a third wiring pattern disposed in a same layer where the first wiring pattern is disposed, and having an area larger than the area of the first wiring pattern,
wherein the resistor is connected so as to straddle the first wiring pattern and the third wiring pattern.

7. The power supply relay unit according to claim 1, further comprising a second switch adapted to be turned on to supply a first current to the load and activate a load-side controller of the load,
wherein the first switch is configured to, after the load-side controller of the load is activated, be turned on based on a request signal from the load-side controller of the load for requesting power supply, to supply a second current larger than the first current to the load.

8. The power supply relay unit according to claim 1, wherein the first switch and the resistor are adapted to be provided between the DC power supply and a server as the load.
